(19) United States
(12) Patent Application Publication
(10) Pub. No.: US 2025/0160167 A1
(43) Pub. Date: May 15, 2025

(54) DISPLAY DEVICE AND METHOD OF MANUFACTURING THE SAME

(71) Applicant: Samsung Display Co., LTD., Yongin-si (KR)

(72) Inventors: Myung Hwan KIM, Yongin-si (KR); Se Joong SHIN, Yongin-si (KR)

(73) Assignee: Samsung Display Co., LTD., Yongin-si (KR)

(21) Appl. No.: 18/751,774

(22) Filed: Jun. 24, 2024

(30) Foreign Application Priority Data
Nov. 13, 2023 (KR) 10-2023-0156810

(51) Int. Cl. H10K 59/80; H10K 59/90; H10K 102/00

(52) U.S. Cl. CPC H10K 59/80; H10K 59/8794; H10K 59/90; H10K 2102/311

(57) ABSTRACT

A display device and a method of manufacturing the same. The display device may include a display panel that may include a first area having a display area, a second area spaced apart from the first area, and a bendable third area located between the first area and the second area; an panel bottom cover bonded to the lower surface of the display panel in the first area; a support film bonded to the lower surface of the display panel in the second area; and a bonding layer to bond the support film to the lower surface of the display panel, wherein a gap between the panel bottom cover and the support film may be disposed in the third area.

### CROSS-REFERENCE TO RELATED APPLICATIONS

This application claims priority under 35 U.S.C. § 119 from Korean Patent Application No. 10-2023-0156810 filed on Nov. 13, 2023 in the Korean Intellectual Property Office, the entire contents of which are incorporated herein by reference.

### BACKGROUND

### 1. Technical Field

The disclosure relates to a display device and a method of manufacturing the same.

### 2. Description of the Related Art

As the information society develops, demands for display devices for displaying images are increasing in various forms. For example, display devices are applied to various electronic devices such as smartphones, digital cameras, notebook computers, navigation devices, and smart televisions.

As display devices, various types of display devices such as liquid crystal displays (LCD) and organic light emitting displays (OLED) may be used. Among them, OLEDs display images using organic light emitting elements that generate light through recombination of electrons and holes. An OLED includes multiple transistors that provide a driving current to an organic light emitting element.

Recently, various attempts have been made to minimize the thickness of display devices in order to make them lighter.

### SUMMARY

Aspects of the disclosure provide a display device which can reduce thickness and manufacturing costs and a method of manufacturing the display device.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device that may include a display panel that may include a first area comprising a display area, a second area spaced apart from the first area, and a bendable third area located between the first area and the second area; a panel bottom cover bonded to a lower surface of the display panel in the first area; a support film bonded to the lower surface of the display panel in the second area; and a bonding layer bonding the support film to the lower surface of the display panel, wherein a gap may be disposed in the third area between the panel bottom cover and the support film.

In an embodiment, the panel bottom cover may comprise a heat dissipation member bonded to the lower surface of the display panel in the first area and dissipating heat from the display panel; an adhesive member bonding the heat dissipation member to the display panel; and a bending adhesive member located at the lower surface of the heat dissipation member and fixing a bent position of the display panel in case that the display panel may be bent.

In an embodiment, the heat dissipation member may comprise a metal layer and a plating layer disposed on at least one surface among an upper surface and a lower surface of the metal layer.

In an embodiment, the adhesive member may comprise a light absorbing material that bonds the heat dissipation member to the lower surface of the display panel and to absorb light irradiated from outside.

In an embodiment, the support film may further include a burr pattern protruding downward from a lower surface of the support film along an inner surface around the gap.

In an embodiment, an angle formed by a connection surface connecting the inner surface of the bonding layer and an inner surface of the support film and the lower surface of the display panel may be about 70 degrees or less.

In an embodiment, the bonding layer may include a light-peelable adhesive and an adhesive strength after irradiation may be about 100 gf/in or less.

In an embodiment, the support film may comprise at least one of polyethylene terephthalate (PET), polycarbonate (PC), and polymethyl methacrylate (PMMA), the bonding layer may comprise at least one of polyester acrylate resin, unsaturated polyester resin, polyurethane acrylate resin, epoxy acrylate resin, epoxy resin, polyether acrylate resin, and polythiol acrylate resin.

In an embodiment, the display device may further include a driving chip disposed in the second area of the display panel and located on an upper surface of the display panel.

In an embodiment, the display device may further include a flexible printed circuit board electrically connected to the driving chip of the second area; and a substrate cover layer disposed on a lower surface of the flexible printed circuit board.

In an embodiment, the flexible printed circuit board may have an end bonded to a distal portion of the display panel in the second area, and the substrate cover layer may be located on the lower surface of the flexible printed circuit board at the distal portion of the display panel and may contact a side surface of the display panel, a side surface of the bonding layer and a side surface of the support film in the second area.

In an embodiment, the substrate cover layer may further include a cover portion extending from a lower surface of the substrate cover layer toward the side surface of the support film which contacts the substrate cover layer and covering a portion of a lower area of the support film.

In an embodiment, the display device may further include a protective layer disposed on at least one of an upper surface and the lower surface of the display panel in the third area.

According to another aspect of the disclosure, there may be provided a display device that may include a display panel comprising a first area comprising a display area, a second area spaced apart from the first area, and a bendable third area located between the first area and the second area; a support film bonded to the lower surface of the display panel in the second area; a bonding layer bonding the support film to the lower surface of the display panel in the second area; a flexible printed circuit board having an end bonded to a distal portion of the display panel in the second area; and a substrate cover layer disposed on a lower surface of the flexible printed circuit board.

In an embodiment, the substrate cover layer may further include a cover portion extending from a lower surface of the substrate cover layer toward a side surface of the support film which contacts the substrate cover layer and covering a portion of a lower area of the support film.

In an embodiment, the display device may further include a panel bottom cover disposed in the first area of the display panel and bonded to the lower surface of the display panel.

In an embodiment, the panel bottom cover may comprise a heat dissipation member bonded to the lower surface of the display panel in the first area and dissipating heat from the display panel; an adhesive member disposed between the heat dissipation member and the lower surface of the display panel and bonding the heat dissipation member; and a bending adhesive member located at the lower surface of the heat dissipation member and fixing a bent position of the display panel in case that the display panel is bent, the third area may comprise a gap which may be a separation space formed between the support film and the heat dissipation member, and the support film may further comprise a burr pattern protruding downward from the lower surface of the support film along an inner surface around the gap.

In an embodiment, the display device may further include a driving chip disposed in the second area of the display panel and located on an upper surface of the display panel.

In an embodiment, the display device may further include a protective layer disposed on at least one of the upper surface and the lower surface of the display panel and in the third area.

According to another aspect of the disclosure, there is provided a method of manufacturing a display device, the method may comprise providing the display device that includes a display panel which comprises a first area comprising a display area, a second area spaced apart from the first area, and a bendable third area comprising a gap between the first area and the second area, a support film layer disposed on the entire lower surface of the display panel in the first through third areas, and a light-peelable bonding body layer to bond support film layer to the display panel; forming a cutting virtual line in the light-peelable bonding body layer and the support film layer at a boundary virtual line between the second area and the third area; selectively irradiating light to the first and third areas of the light-peelable bonding body layer and the support film layer in which the cutting virtual line is formed; forming the light-peelable bonding body layer into a bonding layer in the second area and forming the support film layer into a support film in the second area by peeling and removing the light-peelable bonding body layer and the support film layer of the first and third areas irradiated with the light; and forming a panel bottom cover in the first area at a position spaced apart from the bonding layer and the support film of the second area with the gap disposed between the panel bottom cover and each of the bonding layer and the support film.

In an embodiment, in the step of forming the cutting virtual line, the cutting virtual line may be formed by cutting the optically removable bonding body layer and the support film layer together through laser processing.

In an embodiment, in the step of forming the cutting virtual line, a burr pattern protruding from the support film may be formed in the incision area where the incision line is formed.

In an embodiment, in the step of forming the cutting virtual line, a cutting surface may be formed in each of the optically removable bonding body layer and the support film layer, and an inclination angle between the incision surface and the lower surface of the display panel may be about 70 degrees or less.

In an embodiment, in the step of irradiating the light, a mask including a light transmitting portion corresponding to the first and third regions and a light blocking portion corresponding to the second region may be disposed based on the cutting virtual line.

In an embodiment, in the step of irradiating the light, the adhesive force of the light removable bonding body layer may decrease to about 100 gf/inch or less after the irradiating of the light.

In an embodiment, the step of forming the panel bottom cover may include forming a heat dissipation member located on the lower surface of the display panel in the first area and dissipating heat of the display panel, the lower surface of the display panel in the first area, forming an adhesive member located between the heat dissipating members and coupling the heat dissipating members, and forming a bending adhesive member located on a lower surface of the heat dissipating member in the first area.

In an embodiment, the method may further include forming a protective layer on at least one of the upper and lower surfaces of the display panel in the third area.

In an embodiment, the method may further include forming a driving chip disposed in the second area of the display panel and located on an upper surface of the display panel.

In an embodiment, the method may further include forming a flexible printed circuit board electrically connected to the driving chip and having an end coupled to a distal region of the display panel in the second region, and forming a flexible printed circuit board in the distal region of the display panel. The method may further include forming a substrate cover layer located on a lower surface and in contact with a side surface of the display panel, a side surface of the bonding layer, and a side surface of the support film in the second region.

In an embodiment, in the step of forming the substrate cover layer, the cover portion extending from the lower surface of the substrate cover layer toward the side of the support film in contact with one side of the substrate cover layer and covering a portion of the lower region of the support film may be formed.

Specific details of other embodiments are included in the detailed description and drawings.

According to the present embodiment, a display device capable of reducing thickness and manufacturing costs and a method of manufacturing the display device are provided.

Specifically, in case where a component corresponding to the support film is disposed in a first area, environmental reliability problems may occur when the display panel is bent or folded. However, in the present disclosure, since the component corresponding to the support film is not disposed in the first area, environmental reliability problems may be resolved.

When the component corresponding to the support film is located in the first area, the overall thickness may increase because stacked structures increase in the first area which is a display area. However, according to the present disclosure, the support film is disposed in a second area which is a non-display area and the component corresponding to the support film is not disposed in the first area which is the display area. Therefore, the stacked structures can be reduced in the first area which is the display area, thereby reducing the overall thickness of a display device.

In addition, since the component corresponding to the support film is not disposed in the first area, the stacked structures can be reduced in the first area which is the display area, thereby reducing manufacturing costs.

According to the present disclosure, the component corresponding to the support film is not disposed in the first area, but the support film is located on the lower surface of the display panel at a position corresponding to a driving chip IC of the second area. Therefore, the display panel can be protected in the second area, and the problems of cracks and driving chip defects can be solved.

In addition, since the panel bottom cover is located in the first area, the display panel can be stably supported in the second area.

In addition, a cover portion is formed adjacent to the support film of the second area to seal a portion of a lower surface of the support film. Therefore, it is possible to prevent the penetration of moisture into a flexible printed circuit board (FPCB) and the driving chip IC connected to the flexible printed circuit board (FPCB), thereby preventing corrosion due to the moisture.

In addition, in the manufacturing process, a support film layer may be bonded and then peeled off by a light-peelable bonding body layer whose adhesive strength is reduced by light irradiation. Therefore, the light-peelable bonding body and the support film layer does not remain to cause defects or leave damage to a peeled surface. Accordingly, a defect rate can be reduced, and issues such as tearing during a peeling process can be suppressed.

However, the effects of the disclosure may not be restricted to the one set forth herein. The above and other effects of the disclosure will become more apparent to one of skill in the art to which the disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a plan view of the display device illustrated in FIG. 1;

FIG. 3 is a rear view of the display device illustrated in FIG. 1;

FIG. 4 is a rear view of a display panel in the display device of FIG. 3;

FIG. 5 is a schematic cross-sectional view schematically illustrating the structure of the display panel;

FIG. 6 is an enlarged schematic cross-sectional view of the stacked structure of the display panel of FIG. 5;

FIG. 7 is a schematic cross-sectional view taken along line X1-X1′ of FIGS. 2 and 3;

FIG. 8 is an enlarged view of a first area of FIG. 7;

FIG. 9 is an enlarged view of a boundary area between a second area and a third area of FIG. 7;

FIG. 10 is an enlarged view of the second area and a flexible printed circuit board bonding area of FIG. 7;

FIG. 11 is a schematic cross-sectional view of the display device of FIG. 7 in a bent state;

FIG. 12 is a flowchart illustrating a method of manufacturing a display device according to the disclosure;

FIG. 13 is a perspective view of a mother substrate for a display device;

FIG. 14 rear view of the mother substrate for a display device illustrated in FIG. 13; and

FIGS. 15 through 20 are schematic cross-sectional views for specifically explaining a process of forming a support film, a bonding layer, and a panel bottom cover during the manufacturing process of FIG. 12.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described with reference to the accompanying drawings.

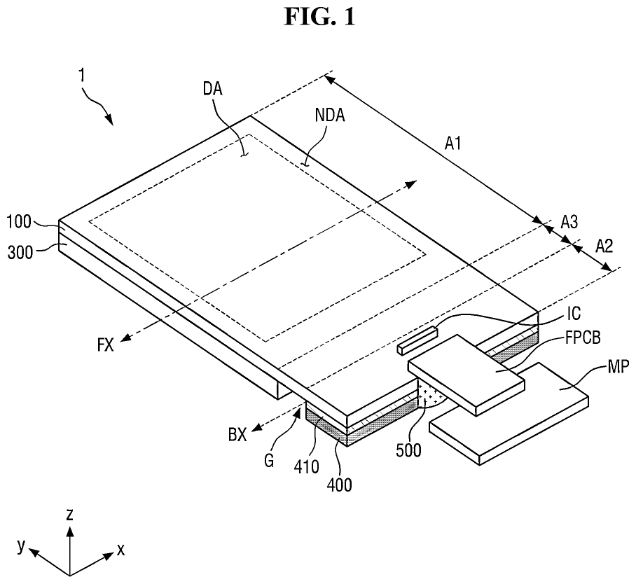

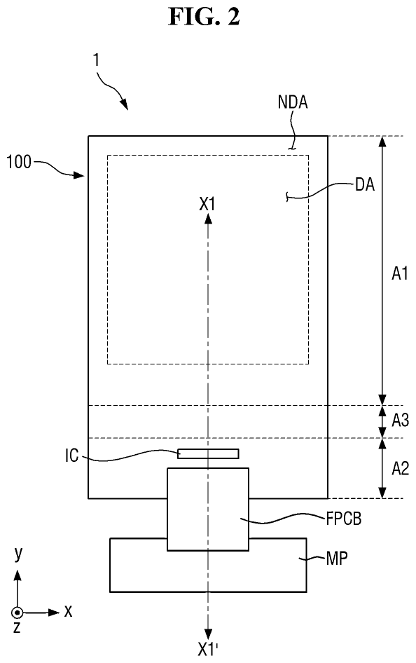

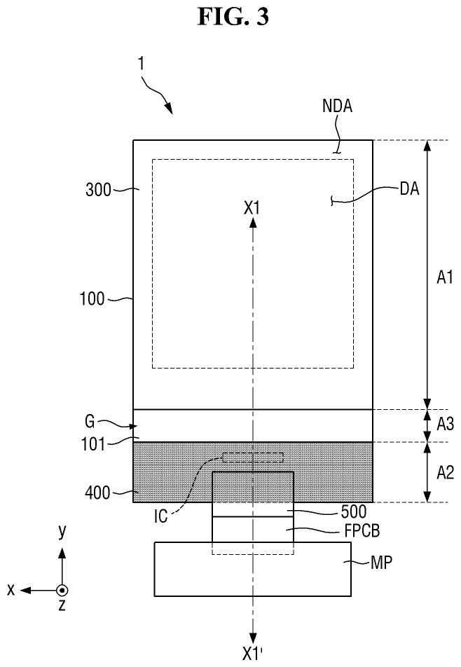

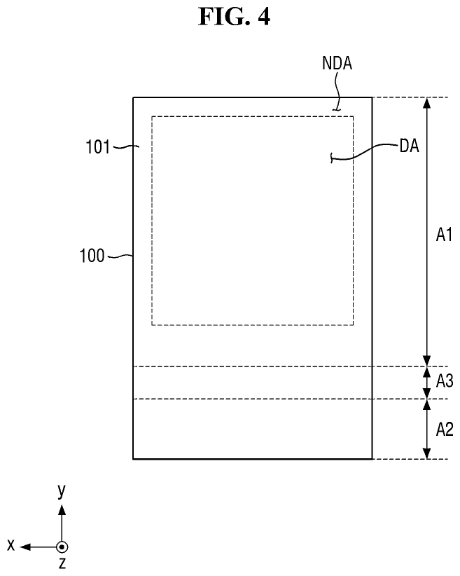

FIG. 1 is a perspective view of a display device 1 according to an embodiment. FIG. 2 is a plan view of the display device 1 illustrated in FIG. 1. FIG. 3 is a rear view of the display device 1 illustrated in FIG. 1. FIG. 4 is a rear view of a display panel 100 in the display device 1 of FIG. 3. Here, FIGS. 1 through 4 illustrate the display device 1 before being bent or folded.

A display device 1 may be applied to a portable terminal or the like. Examples of the portable terminal may include tablet PCs, smartphones, personal digital assistants (PDAs), portable multimedia players (PMPs), game consoles, and wristwatch-type electronic devices. However, the disclosure is not limited to the specific type of display device 1. For example, in other embodiments of the disclosure, the display device 1 may be used in small and medium-sized electronic equipment such as PCs, notebook computers, car navigation devices and cameras as well as in large-sized electronic equipment such as televisions and outdoor billboards.

In an embodiment, the display device 1 may include a display panel 100 having a rectangular shape.

The display panel 100 may have a rectangular shape in a plan view and may include both short sides, both long sides, and a rectangular panel surface formed by the short sides and the long sides.

The display panel 100 may be illustrated as a rectangular planar shape in which each corner where a long side and a short side meet may be right-angled. However, the disclosure is not limited thereto. The corners of the display panel 100 may also be curved, and the planar shape of the display panel 100 may also be circular or other various shapes.

Based on the state illustrated in FIG. 1, the short sides of the display panel 100 will be described as a first direction x, the long sides of the display panel 100 will be described as a second direction y, and a direction perpendicular to a panel direction formed by the panel surface of the display panel 100 will be described as a third direction z. Unless otherwise defined below, in the specification, “above”, “top”, “upper surface”, and “upper side” may refer to a direction in which an arrow of the third direction z points with respect to the display panel 100, and “below”, “bottom”, “lower surface”, and “lower side” refer to a direction opposite to the direction in which the arrow of the third direction z points with respect to the display panel 100.

The display panel 100 may be a display panel 100 including a self-light emitting element. In an embodiment, the self-light emitting element may include at least one of an organic light emitting diode, a quantum dot light emitting diode, an inorganic material-based micro light emitting diode (e.g., micro LED), and an inorganic material-based nano light emitting diode (e.g., nano LED). For ease of description, each element of the display panel 100 will be described in detail below using a case where the self-light emitting element may be an organic light emitting element as an example.

In case that the display panel 100 is divided based on image display, it may include a display area DA which displays an image and a non-display area NDA which does not display an image. The non-display area NDA may be located around the display area DA and may surround the display area DA.

In case that the display panel 100 is divided based on a bendable area, it may include a first area A1, a second area A2, and a third area A3.

The display panel 100 may include the first area A1 including the display area DA, the second area A2 spaced apart from the first area A1, and the bendable third area A3 positioned between the first area A1 and the second area A2.

A gap G which may be a space between the first area A1 and the second area A2 may be formed in the third area A3, and the first area A1 and the second area A2 may be positioned to be spaced apart by the gap G of the third area A3.

The first area A1 may be foldable. For example, the first area A1 can be folded upward or downward based on a folding axis FX extending in the first direction x.

If explained based on FIG. 1, the first area A1 can be folded in the direction in which the arrow of the third direction z points, that being the upward direction or in the direction opposite to the direction in which the arrow of the third direction z points, that being the downward direction.

A panel bottom cover 300 may be located at the lower side of the display panel 100 in the first area A1.

The panel bottom cover 300 of the first area A1 may be bonded on the lower side of the display panel 100 at a location spaced apart from the second area A2 by the gap G.

The second area A2 may be another part of the non-display area NDA.

A bonding layer 410 and a support film 400 may be located on the lower side of the display panel 100 in the second area A2.

The bonding layer 410 and the support film 400 of the second area A2 may be bonded to the lower side of the display panel 100 at a position spaced apart from the first area A1 by the gap G.

The gap G of the third area A3 may be located between the bonding layer 410 and the support film 400 of the second area A2 and the panel bottom cover 300 of the first area A1.

In the second area A2, the driving chip IC and an end area of a flexible printed circuit board FPCB may be located on the upper side of the display panel 100. Here, a main circuit board MP may be electrically connected to another end area of the flexible printed circuit board FPCB.

Pads electrically connected to the driving chip IC and pads electrically connected to the flexible printed circuit board FPCB may be located in the second area A2. A substrate cover layer 500 in contact with the display panel 100, the bonding layer 410, and the support film 400 may be located on the lower side of the flexible printed circuit board FPCB.

The driving chip IC and flexible printed circuit board FPCB of the second area A2 may be located on the upper side of the display panel 100 at a position spaced apart from the first area A1.

The driving chip IC may include at least one of driving devices such as a data driver which transmits data signals to data lines, a gate driver which transmits gate signals to gate lines, and a signal controller which controls the operations of the data driver and the gate driver. The number of driving chips IC is not limited to the illustrated example.

The driving chip IC may be mounted on the display panel 100 using a chip on plastic method. The driving chip IC may be mounted on the display panel 100 using a pressurizing device. The driving chip IC may be mounted on the display panel 100 using an anisotropic conductive film. In an embodiment, the driving chip IC may be mounted on the display panel 100 using an ultrasonic bonding method without a separate anisotropic conductive film.

Ultrasonic bonding may be a method of joining two metals by applying pressure and ultrasonic vibration. In case that the driving chip IC is mounted on the display panel 100 using the ultrasonic bonding method, a process of applying pressure and ultrasonic vibration to the driving chip IC may be performed. However, the disclosure is not limited to the above-described embodiment. In an embodiment, the driving chip IC may be mounted on a flexible printed circuit board FPCB in the form of a chip on film.

The flexible printed circuit board FPCB may be electrically connected to the second area A2 of the display panel 100. The flexible printed circuit board FPCB may be electrically connected to the pads provided on the display panel 100 by an anisotropic conductive film or the like. The process of connecting the flexible printed circuit board FPCB to the display panel 100 may include a process of applying pressure to the flexible printed circuit board FPCB.

A main circuit board MP may be electrically connected to the display panel 100 through the flexible printed circuit board FPCB and may exchange signals with the driving chip IC. The main circuit board MP may provide image data, control signals, power supply voltages, etc. to the display panel 100 or the flexible printed circuit board FPCB. The main circuit board MP may include active and passive elements.

The third area A3 may be still another part of the non-display area NDA.

The third area A3 may be located between the first area A1 and the second area A2, and may include the gap G which may be a separation space formed between the panel bottom cover 300 of the first area A1 and the support film 400 of the second area A2. Specifically, the gap G may be defined as the separation space between the support film 400 and the heat dissipation member 330 of the panel bottom cover 300, which will be described later.

The gap G of the third area A3 may be formed in a direction intersecting the non-display area NDA in the first direction x, which may be the short side direction of the display panel 100.

The display panel 100 can be bent based on a bending axis BX extending in the first direction x in the third area A3 and the display panel 100 can be bent downward based on the bending axis BX in the third area A3. As a part of the non-display area NDA of the display panel 100 may be bent toward the bottom of the display panel 100, the non-display area NDA of the display device 1 which may be visible from above can be reduced, and a bezel width of the display device 1 can be reduced.

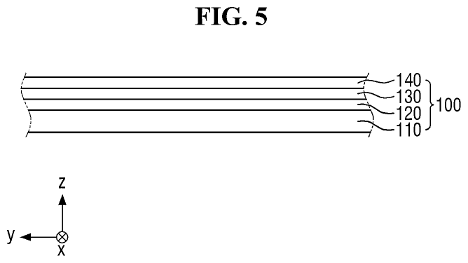

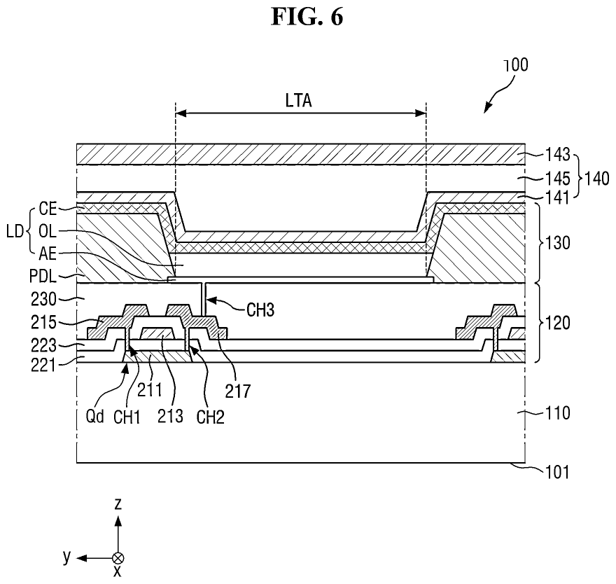

FIG. 5 is a schematic cross-sectional view schematically illustrating the structure of the display panel. FIG. 6 is a schematic enlarged cross-sectional view of the stacked structure of the display panel of FIG. 5.

The display panel 100 may include a base substrate 110, a driving layer 120, an organic light emitting element layer 130, and an encapsulation layer 140.

The base substrate 110 provides a lower surface 101 of the display panel 100. The base substrate 110 may be a flexible substrate and may be made of a flexible polymer material. For example, the base substrate 110 may be made of plastic with excellent heat resistance and durability, such as polyethylene ether phthalate, polyethylene naphthalate, polycarbonate, polyarylate, polyetherimide, polyethersulfone, polyimide, or a combination thereof. A case where the base substrate 110 includes polyimide will be described below as an example.

The driving layer 120 includes elements for providing signals to the organic light emitting element layer 130. The driving layer 120 may include various signal lines, for example, scan lines (not illustrated), data lines (not illustrated), power lines (not illustrated), and emission lines (not illustrated). The driving layer 120 may include multiple transistors and capacitors. The transistors may include a switching transistor (not illustrated) and a driving transistor Qd provided in each pixel (not illustrated).

In FIG. 6, the driving transistor Qd of the driving layer 120 may be illustrated as an example. The driving transistor Qd includes an active layer 211, a gate electrode 213, a source electrode 215, and a drain electrode 217.

The active layer 211 may be disposed on the base substrate 110. The active layer 211 may include polycrystalline silicon. The active layer 211 may include monocrystalline silicon, low-temperature polycrystalline silicon, amorphous silicon, or a combination thereof. However, the disclosure is not limited thereto, and the active layer 211 may also include an oxide semiconductor.

The driving layer 120 may further include a first insulating layer 221 disposed on the active layer 211, and the gate electrode 213 may be located on the first insulating layer 221.

The first insulating layer 221 may insulate the active layer 211 and the gate electrode 213 from each other. The first insulating layer 221 may include an inorganic insulating material such as silicon oxide, silicon nitride, silicon oxynitride, or a combination thereof. The first insulating layer 221 may be a single layer or a multilayer composed of stacked layers of different materials.

The gate electrode 213 may be located on the first insulating layer 221 and may overlap the active layer 211. The gate electrode 213 may include gold (Au), silver (Ag), copper (Cu), nickel (Ni), platinum (Pt), palladium (Pd), aluminum (Al), molybdenum (Mo), or a combination thereof.

The driving layer 120 may further include a second insulating layer 223 located on the gate electrode 213, and the source electrode 215 and the drain electrode 217 may be disposed on the second insulating layer 223.

The second insulating layer 223 may include at least any one of the insulating materials exemplified in the description of the first insulating layer 221.

The source electrode 215 and the drain electrode 217 may be respectively electrically connected to the active layer 211 through contact holes CH1 and CH2 provided in the first insulating layer 221 and the second insulating layer 223. The source electrode 215 and the drain electrode 217 may have, but are not limited to, a metal multilayer structure of titanium (Ti)/aluminum (Al)/titanium (Ti).

The driving layer 120 may further include a protective layer 230 disposed on the source electrode 215 and the drain electrode 217. In some embodiments, the protective layer 230 may be a planarization layer. For example, the protective layer 230 may include an organic insulating material or an inorganic insulating material or may be implemented as a composite of an organic insulating material and an inorganic insulating material.

Although the structure of the switching transistor may not be illustrated in FIG. 6, the switching transistor (not illustrated) and the driving transistor Qd may have substantially a same structure or similar structures. However, the disclosure is not limited thereto, and the switching transistor (not illustrated) and the driving transistor Qd may also have different structures. For example, an active layer (not illustrated) of the switching transistor (not illustrated) and the active layer 211 of the driving transistor Qd may be made of different materials or may be disposed on different layers.

The driving layer 120 may be located not only in the display area DA but also in the non-display area NDA of the display panel 100. A portion of the driving layer 120 which may be located in the non-display area NDA, for example, a portion located in the non-display area NDA of the first area A1, in the second area A2, and in the third area A3 may include wirings and a pad portion electrically connected to the driving chip IC and may further include wirings and a pad portion electrically connected to the flexible printed circuit board FPCB.

The organic light emitting element layer 130 may include an organic light emitting element LD as a self-light emitting element. The organic light emitting element LD may be provided as a top emission type and may emit light in a thickness direction of the display panel 100 or in the third direction z.

The organic light emitting element LD may include a first electrode AE, an organic layer OL, and a second electrode CE.

The first electrode AE may be disposed on the protective layer 230. The first electrode AE may be electrically connected to the drain electrode 217 through a contact hole CH3 formed in the protective layer 230. The first electrode AE may be a pixel electrode or an anode. The first electrode AE may be a transflective electrode or a reflective electrode. In case that the organic light emitting element LD is provided as a top emission type, the first electrode AE may be a reflective electrode. The first electrode AE may include any one of silver (Ag), magnesium (Mg), aluminum (Al), platinum (Pt), palladium (Pd), gold (Au), nickel (Ni), neodymium (Nd), iridium (Ir) and chromium (Cr), an alloy thereof, or a combination thereof.

The first electrode AE may be a single layer made of metal oxide or metal or a multilayer structure having multiple layers. For example, the first electrode AE may have, but is not limited to, a single layer structure of indium tin oxide (ITO), silver (Ag) or a metal mixture (e.g., a mixture of Ag and Mg), a two-layer structure of indium tin oxide (ITO)/magnesium (Mg) or indium tin oxide (ITO)/magnesium fluoride (MgF), or a three-layer structure of indium tin oxide (ITO)/silver (Ag)/indium tin oxide (ITO).

The organic layer OL may include an organic emission layer (EML) made of a low-molecular organic material or a high-molecular organic material. The organic emission layer may emit light. The organic layer OL may optionally include a hole transport layer (HTL), a hole injection layer (HIL), an electron transport layer (ETL), and an electron injection layer (EIL), in addition to the organic emission layer.

Holes and electrons from the first electrode AE and the second electrode CE, respectively may be injected into the organic emission layer inside the organic layer OL. The holes and the electrons may be combined in the organic emission layer to form excitons, and light may be emitted as the excitons fall from an excited state to a ground state.

The second electrode CE may be provided on the organic layer OL. The second electrode CE may be a common electrode or a cathode. The second electrode CE may be a transmissive electrode or a transflective electrode. In case that the second electrode CE is a transflective electrode, it may include lithium (Li), lithium fluoride (LiF), calcium (Ca), lithium fluoride (LiF)/calcium (Ca), lithium fluoride (LiF)/aluminum (Al), aluminum (Al), magnesium (Mg), barium fluoride (BaF), barium (Ba), silver (Ag), a compound or mixture thereof (e.g., a mixture of Ag and Mg).

In case that the second electrode CE is a transmissive electrode, it may include a transparent metal oxide such as indium tin oxide (ITO), indium zinc oxide (IZO), zinc oxide (ZnO) or indium tin zinc oxide (ITZO) or may include molybdenum (Mo), titanium (Ti) silver (Ag), or a combination thereof.

The organic light emitting element layer 130 may further include a pixel defining layer PDL disposed on the protective layer 230. The pixel defining layer PDL may include an opening, and define an emission area LTA.

The encapsulation layer 140 may be disposed on the organic light emitting element layer 130. The encapsulation layer 140 may block the organic light emitting element layer 130 from external moisture and oxygen.

The encapsulation layer 140 may be formed as thin-film encapsulation and may include one or more organic layers and one or more inorganic layers. For example, the encapsulation layer 140 may include a first inorganic layer 141 located on the second electrode CE, an organic layer 145 located on the first inorganic layer 141, and a second inorganic layer 143 located on the organic layer 145.

The first inorganic layer 141 may be disposed on the organic light emitting element LD and may prevent the penetration of moisture, oxygen, etc. into the organic light emitting element LD. In some embodiments, the first inorganic layer 141 may include an inorganic material, and the inorganic material may include, for example, any one or more of silicon oxide (SiOₓ), silicon nitride (SiNₓ), and silicon oxynitride (SiONₓ).

The organic layer 145 may be located on the first inorganic layer 141. The organic layer 145 may improve flatness. The organic layer 145 may include an organic material, and the organic material may include, for example, any one of epoxy, acrylate, urethane acrylate, or a combination thereof.

The second inorganic layer 143 may be located on the organic layer 145. The second inorganic layer 143 may perform substantially the same or similar role as the first inorganic layer 141 and may be made of substantially the same or similar material as the first inorganic layer 141. The second inorganic layer 143 may completely cover the organic layer 145. In some embodiments, the second inorganic layer 143 and the first inorganic layer 141 may contact each other outside the display area DA to form an inorganic-inorganic bond. In case that the inorganic-inorganic bond is formed, it may be possible to effectively prevent the introduction of moisture into the display device 1 from the outside of the display device 1.

Although each of the first inorganic layer 141, the organic layer 145, and the second inorganic layer 143 may be illustrated as a single layer in FIG. 6, the disclosure is not limited thereto. At least one of the first inorganic layer 141, the organic layer 145, and the second inorganic layer 143 may also be formed in a multilayer structure.

The encapsulation layer 140 may not completely cover the non-display area NDA of the display panel 100. For example, the encapsulation layer 140 may not be located in a part of the first area A1 of the display panel 100 between the third area A3 and the display area DA and may not be located in the second area A2 and the third area A3. The encapsulation layer 140 may be located in a part of the first area A1 of the display panel 100 between the third area A3 and the display area DA and may not be located in the second area A2 and the third area A3. For ease of description, a case where the encapsulation layer 140 may be located in the display area DA of the display panel 100 and may not be located in a part of the first area A1 between the third area A3 and the display area DA and not located in the second area A2 and the third area A3 will be described as an example.

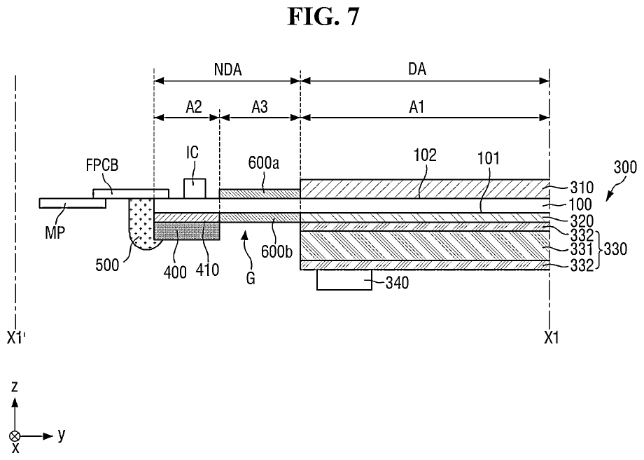

FIG. 7 is a schematic cross-sectional view taken along line X1-X1′ of FIGS. 2 and 3 and a schematic cross-sectional view of the display panel 100 on which a panel bottom cover 300, a support film 400, and a substrate cover layer 500 may be located in the first through third areas A1 through A3.

A polarizer 310 may be located on an upper surface 102 of the display panel 100 in the first area A1. Here, the polarizer 310 increases contrast ratio by expressing true black and may be located on an upper surface 102 of the display panel 100 to secure outdoor visibility.

The panel bottom cover 300 of the first area A1 may be located on the lower surface 101 of the display panel 100 in the first area A1 and may support the display panel 100.

The panel bottom cover 300 may include an adhesive member 320 attached to the lower surface 101 of the display panel 100, a heat dissipation member 330 for efficiently dissipating heat from the display panel 100, and a bending adhesive member 340 for fixing a bent position (or bent shape or bent state or bent configuration) of the display panel 100 in case that the display panel 100 is bent.

The adhesive member 320 may be disposed between the lower surface 101 of the display panel 100 and the heat dissipation member 330 to attach the panel bottom cover 300 to lower surface 101 of the display panel 100.

The adhesive member 320 may be an adhesive layer made of a pressure sensitive adhesive (PSA) and may attach the panel bottom cover 300 to the lower surface 101 of the display panel 100. For example, the adhesive member 320 may include, but is not limited to, an acrylic or silicone adhesive.

The adhesive member 320 may be formed as a pressure sensitive adhesive layer that further includes a light absorbing material such as black pigment or black dye to absorb light incident from the outside.

The heat dissipation member 330 may be bonded by the adhesive member 320 and may include a metal layer 331 and a plating layer 332 formed on at least one of upper and lower surfaces of the metal layer 331.

The metal layer 331 may be, but is not limited to, a thin film made of one or more metals selected from copper, nickel, ferrite, and silver with excellent thermal conductivity.

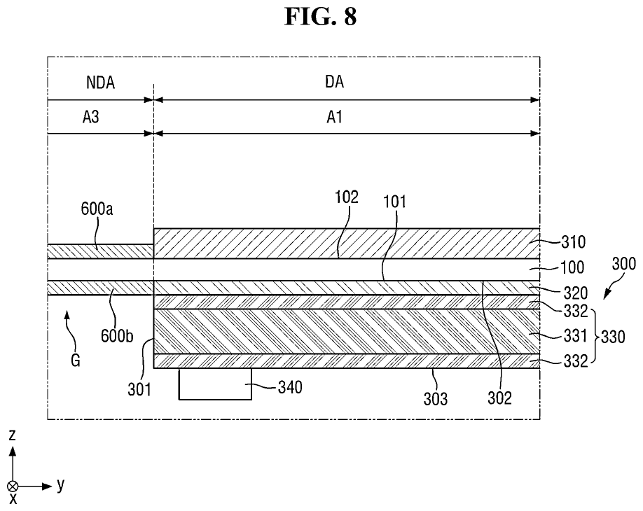

The plating layer 332 may be made of the same or different metal. Although the plating layer 332 may be formed on both the upper and lower surfaces of the metal layer 331 in FIG. 8, it may also be formed on only one surface.

The heat dissipation member 330 may also be, but is not limited to, a composite layer including, for example, a first layer containing graphite or carbon nanotubes and a second layer made of a metal thin film such as copper, nickel, ferrite, silver, or a combination thereof which can shield electromagnetic waves and has excellent thermal conductivity.

The bending adhesive member 340 fixes the bent position of the display panel 100 in case that the display panel 100 is bent. The position of the display panel 100 may be fixed as the support film 400 may be attached to the bending adhesive member 340 at the bent position. The bending adhesive member 340 may include, but is not limited to, an acrylic or silicone adhesive.

The panel bottom cover 300 may further include a buffer member (not illustrated). The buffer member may be located on the heat dissipation member 330 and the bending adhesive member 340. The buffer member (not illustrated) may be formed as a cushion layer to support the display panel 100 and prevent damage to the display panel 100 by absorbing external shock. For example, the buffer member (not illustrated) may be made of polymer resin such as polyurethane, polycarbonate, polypropylene, polyethylene, or a combination thereof, or may be made of an elastic material such as a sponge formed by foam molding rubber, a urethane-based material, an acrylic-based material, or a combination thereof.

The support film 400 of the second area A2 may be spaced apart from the heat dissipation member 330 of the panel bottom cover 300 by the gap G. The support film 400 and the heat dissipation member 330 spaced apart from each other may be disposed parallel to each other.

The support film 400 may be located on the lower surface 101 of the display panel 100 at a position corresponding to the driving chip IC in a vertical direction.

The support film 400 may be made of at least one of, for example, polyethylene terephthalate (PET), polycarbonate (PC), and polymethyl methacrylate (PMMA). The support film 400 may be most preferably made of polyethylene terephthalate (PET), but the disclosure is not limited thereto.

The support film 400 may be made of a film with high tensile modulus or high light transmittance.

In case that the support film 400 is made of a film with a high tensile modulus, it can support the flexible display panel 100, protect the lower surface 101 of the display panel 100, and prevent the formation of cracks during a process of mounting the driving chip IC.

In case that the driving chip IC is mounted on the second area A2 of the display panel 100, pressure may be applied to the second area A2. Here, since the support film 400 disposed on the lower surface 101 of the display panel 100 corresponding to the second area A2 has a high tensile modulus, it may be possible to prevent cracks from being formed in the wirings of the non-display area NDA due to the pressure applied during the process of mounting the driving chip IC.

In case that the support film 400 is made of a film with high transmittance, the light transmittance of the support film 400 may be, but is not limited to, about 80% or more.

In case that the support film 400 is made of a film with high transmittance, the driving chip IC may be mounted on the display panel 100 by high-pressure bonding in the second area A2 to which the support film 400 is bonded. Whether the driving chip IC has been properly mounted can be inspected using an optical microscope or the like.

Here, since the light transmittance of the support film 400 located in the second area A2 where the driving chip IC may be mounted may be high, the mounted state of the driving chip IC can be inspected more smoothly. Accordingly, the problem of defects caused by compression of the driving chip IC can be solved.

In the case of the first area A1 being spaced apart from the second area A2, the display panel 100 may be folded along the folding axis FX. Here, if the component corresponding to the support film 400 were to be disposed in the first area A1 that is foldable, problems may occur in environmental reliability. Environmental reliability may refer to the characteristic of the display panel 100 not being broken by maintaining a neutral plane in a high temperature environment in a range of about 60 to about 85 degrees Celsius for bending or folding the display panel 100.

In case where the component corresponding to the support film 400 were to be disposed in the first area A1, environmental reliability problems may occur in case that the display panel is bent or folded. However, in the disclosure, since the component corresponding to the support film 400 may not be disposed in the first area A1, environmental reliability problems may be resolved.

If the support film 400 is located in the first area A1, the overall thickness may increase because stacked structures increase in the first area A1 which is the display area DA. However, according to the disclosure, the support film 400 may be disposed in the second area A2 which may be the non-display area NDA and the component corresponding to the support film 400 may not be disposed in the first area A1 which is the display area DA. Therefore, the stacked structures can be reduced in the first area A1 which is the display area DA, thereby reducing the overall thickness of the display device 1.

Since the component corresponding to the support film 400 may not be disposed in the first area A1, the stacked structures can be reduced in the first area A1 which is the display area DA, thereby reducing manufacturing costs.

According to the disclosure, the component corresponding to the support film 400 may not be disposed in the first area A1, but may be located on the lower surface 101 of the display panel 100 at a position corresponding to the driving chip IC of the second area A2. Therefore, the display panel 100 can be protected in the second area A2, and the problems of cracks and driving chip IC defects can be solved.

The bonding layer 410 in the second area A2 may bond the support film 400 to the lower surface 101 of the display panel 100 in the second area A2.

The bonding layer 410 may be disposed at a position spaced apart in the horizontal direction from the adhesive member 320 of the panel bottom cover 300. The bonding layer 410 and the adhesive member 320 spaced apart from each other may be disposed parallel to each other.

The bonding layer 410 may be located on the lower surface 101 of the display panel 100 at a position corresponding to the driving chip IC in a vertical direction.

The bonding layer 410 may be formed in a shape corresponding to the support film 400, and be disposed between the lower surface 101 of the display panel 100 and the support film 400 to serve the role of attaching the support film 400 to the lower surface 101 of the display panel 100 in the second area A2.

The bonding layer 410 may have adhesiveness that can attach the support film 400 and may be formed to have a high storage modulus.

The bonding layer 410 may include, for example, one or more of polyester acrylate resin, unsaturated polyester resin, polyurethane acrylate resin, epoxy acrylate resin, epoxy resin, polyether acrylate resin, and polythiol acrylate resin. The bonding layer 410 may most preferably include an ultraviolet (UV)-peelable adhesive, but the disclosure is not limited thereto.

In case that the bonding layer 410 is formed of an ultraviolet (UV)-peelable adhesive, it may be desirable for the adhesive strength to be reduced to about 100 gf/in (about 180 degree peeling, speed about 40 mm/sec) or less upon exposure to UV irradiation, but the disclosure is not limited thereto. Here, in case that the bonding layer 410 is formed of an ultraviolet (UV)-peelable adhesive and the adhesive strength is reduced to about 100 gf/in (about 180 degree peeling, speed about 40 mm/sec) or less after light irradiation, process convenience can be improved since peeling may readily occur during the manufacturing process and the defect rate can be reduced by leaving no residue on the peeling surface or damage to the peeling surface.

In case that the storage modulus of the bonding layer 410 is high, it may be possible to prevent cracks from being formed by pressure during the process of mounting the driving chip IC because the bonding layer 410 having a high storage modulus may be located in the second area A2 of the display panel 100.

The substrate cover layer 500 may be disposed on a lower surface of the flexible printed circuit board FPCB to be in contact with the bonding layer 410, the support film 400, and the display panel 100 of the second area A2.

The substrate cover layer 500 may be formed in various forms of organic material and may include, for example, one or more of acrylic resin and urethane resin. However, the disclosure is not limited thereto.

The third area A3 may be located between the second area A2 where the support film 400 and the bonding layer 410 are located and the first area A1 where the panel bottom cover 300 is located.

The third area A3 may be a bendable area, and in order to form a small radius of curvature, the third area A3 may include the gap G, which may be a separation space between the heat dissipation member 330 of the panel bottom cover 300 located in the first area A1 and the support film 400 of the second area A2.

The lower surface 101 of the display panel 100 corresponding to the third area A3 may be exposed through the gap G, and a lower protective layer 600b to be described later, covering the lower surface 101 of the display panel 100 exposed by the gap G, may be exposed.

In the third area A3, upper and lower protective layers 600a and 600b may be located on upper and lower surfaces 102 and 101 of the display panel 100, respectively. Each of the protective layers 600a and 600b may be disposed at a position between the first area A1 and the second area A2.

The upper protective layer 600a may be located between the polarizer 310 of the first area A1 and the driving chip IC of the second area A2 in the horizontal direction and may be disposed on the upper surface 102 of the display panel 100.

The upper protective layer 600a may be located as a neutral plane adjustment layer on the non-display area NDA of the display panel 100.

The neutral plane adjustment layer (or upper protective layer 600a) 600a may overlap the bendable third area A3 of the non-display area NDA of the display panel 100. Although the neutral plane adjustment layer 600a may be formed only in the third area A3, a portion of the neutral plane adjustment layer or 600a may also be formed to overlap the first area A1 and the second area A2.

The neutral plane adjustment layer 600a may prevent the formation of cracks in the wirings in the driving layer 120 by relieving the stress applied to the driving layer 120 in the bendable third area A3.

More specifically, the driving layer 120 may include wirings passing through the non-display area NDA of the first area A1 and the third area A3, and elements in the driving layer 120 may be electrically connected to the driving chip IC through the wirings.

The neutral plane adjustment layer adjusts the position of the neutral plane to prevent tensile stress from acting on the wirings located in the third area A3.

Here, the neutral plane refers to a plane on which neither compressive stress nor tensile stress acts in case that the third area A3 of the display panel 100 is bent. For example, in case that the third area A3 is bent, compressive stress acts on the inside of a bending curvature, and tensile stress acts on the outside.

Therefore, from the inside toward the outside of the curvature, the direction of stress gradually changes from a compression direction to a tension direction. At a certain critical point, there may be a transition point where neither compressive stress nor tensile stress acts, and this point becomes the neutral plane. If the position of the neutral plane may be adjusted by the neutral plane adjustment layer 600a, compressive stress acts on the wirings in the driving layer 120, thereby reducing the risk of crack formation.

The neutral plane adjustment layer 600a may be made of an organic material. The organic material may be, for example, a photosensitive organic material. For example, the neutral plane adjustment layer 600a may include one or more of acrylic resin and urethane resin.

Although the neutral plane adjustment layer 600a may be spaced apart from the driving chip IC in the drawing, the disclosure is not limited thereto. The neutral plane adjustment layer 600a may also extend to a part where the driving chip IC may be disposed and may cover a portion of the driving chip IC.

In this case, the coupling reliability between the driving chip IC and the display panel 100 can be improved.

The lower protective layer 600b may be located between the adhesive member 320 of the first area A1 and the bonding layer 410 of the second area A2 and may be disposed on the lower surface 101 of the display panel 100.

The lower protective layer 600b and the upper protective layer 600a may be made of a same material and may include, for example, one or more of acrylic resin and urethane resin. The lower protective layer 600b may also be made of a different material from that of the upper protective layer 600a.

The lower protective layer 600b may support the lower surface 101 of the display panel 100 in the third area A3 exposed by the gap G and protect the lower surface 101 of the display panel 100. Although both the upper and lower protective layers 600a and 600b may be included in FIG. 7, the disclosure is not limited thereto, and the lower protective layer 600b may also be selectively formed.

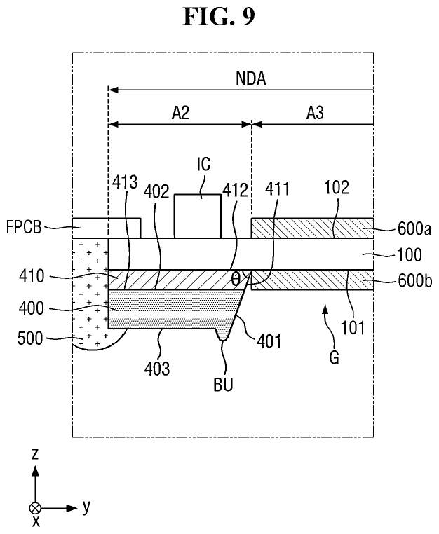

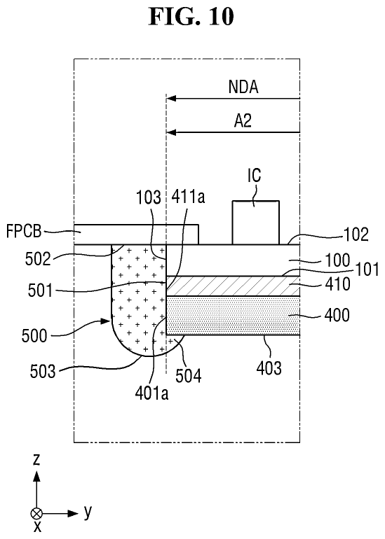

FIG. 8 is an enlarged view of the first area A1 of FIG. 7, FIG. 9 is an enlarged view of a boundary area between the second area A2 and the third area A3 of FIG. 7, and FIG. 10 is an enlarged view of the second area A2 and a flexible printed circuit board bonding area of FIG. 7.

The panel bottom cover 300 of FIG. 8 may include an inner surface 301 around the gap G, an upper surface 302 facing the display panel 100, and a lower surface 303 opposite the upper surface 302.

An angle formed by the inner surface 301 of the panel bottom cover 300 and the lower surface 101 of the display panel 100 may be a right angle. The panel bottom cover 300 may have a rectangular cross-sectional shape as illustrated in FIG. 8. However, the shape of the panel bottom cover 300 is not limited to the rectangular shape.

The support film 400 of FIG. 9 includes an inner surface 401 around the gap G, an upper surface 402 facing the bonding layer 410, and a lower surface 403 opposite the upper surface 402.

The support film 400 may further include a burr pattern BU protruding downward from the lower surface 403 along the inner surface 401 around the gap G.

The burr pattern BU of the support film 400 may be formed in a process of irradiating laser light to the support film 400 during the manufacturing process. The burr pattern BU may be formed as a portion of the support film 400 may be melted by the thermal energy of the laser light.

The burr pattern BU of the support film 400 may protrude downward from the lower surface 403 of the support film 400. The burr pattern BU may extend in the same direction as the gap G, for example, in the first direction x.

The bonding layer 410 may include an inner surface 411 around the gap G, an upper surface 412 facing the display panel 100, and a lower surface 413 opposite the upper surface 412.

Here, the lower surface 413 of the bonding layer 410 may be in contact with the upper surface 402 of the support film 400.

An inclination angle θ formed by the lower surface 101 of the display panel 100 and connection inclined virtual lines 401 and 411 of the connection surface connecting the inner surface 411 of the bonding layer 410 and the inner surface 401 of the support film 400 may be an acute angle. For example, the inclination angle θ may be in a range of about 0 degrees to about 70 degrees. However, the disclosure is not limited thereto. For example, the inclination angle θ in FIG. 9 may be smaller than the angle formed by the inner surface 301 of the panel bottom cover 300 and the lower surface 101 of the display panel 100, but the disclosure is not limited thereto.

The substrate cover layer 500 of FIG. 10 may include a cover layer side surface 501 in contact with respective side surfaces 401a, 411a and 103 of the bonding layer 410, the support film 400 and the display panel 100, a cover layer upper surface 502 in contact with the lower surface of the flexible printed circuit board FPCB, and a cover layer lower surface 503 opposite the cover layer upper surface 502.

The cover layer upper surface 502 supports the flexible printed circuit board FPCB from below the flexible printed circuit board FPCB, and the cover layer side surface 501 supports the respective side surfaces 401a, 411a and 103 of the bonding layer 410, the support film 400 and the display panel 100 from the side.

As illustrated in FIG. 10, the substrate cover layer 500 may further include a cover portion 504 extending from the cover layer lower surface 503 toward the side surface 401a of the support film 400.

The cover portion 504 may be formed to cover, that is, seal a portion of the lower surface 403 of the support film 400. Therefore, it may be possible to prevent the penetration of moisture into the flexible printed circuit board FPCB and the driving chip IC electrically connected to the flexible printed circuit board FPCB, thereby preventing corrosion due to the moisture.

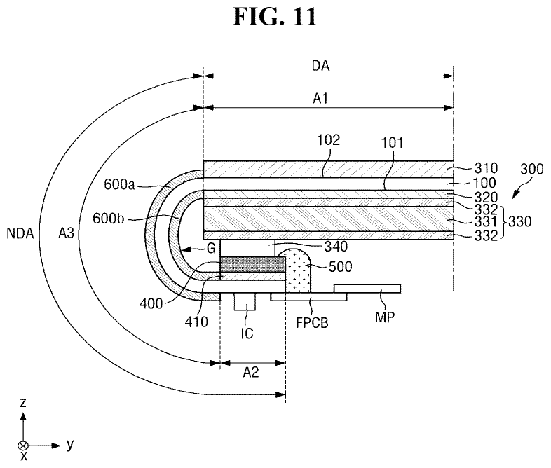

FIG. 11 is a schematic cross-sectional view of the display device of FIG. 7 in a bent state, more specifically, a schematic cross-sectional view of the non-display area in a bent state.

Referring to the drawing, the display panel 100 of the display device 1 may be bent toward the bottom of the display panel 100 based on the bending axis BX (see FIG. 1) extending in the first direction x in the third area A3.

Since the gap G overlapping the third area A3 may be defined between the panel bottom cover 300 and the support film 400, the display panel 100 can be bent more readily. Here, as the support film 400 may be coupled to the bending adhesive member 340 of the panel bottom cover 300, the bent position of the display panel 100 may be fixed by the bending adhesive member 340.

Depending on the position at which the support film 400 may be attached to the bending adhesive member 340, the alignment state can be changed. For example, the display panel 100, the support film 400, and the bonding layer 410 may all be aligned with the bending adhesive member 340 in a row in the vertical direction. As illustrated in FIG. 11, the display panel 100, the support film 400, and the bonding layer 410 may be fixed to form a step with the bending adhesive member 340 by moving the support film 400 to the right and fixing the support film 400 in that position.

Since a part of the non-display area NDA of the display panel 100 may be bent, the area of the non-display area NDA of the display device 1 which may be visible from the outside can be reduced, and the bezel width of the display device 1 can be reduced. Since the neutral plane adjustment layer 600a overlapping the third area A3 may be located on the display panel 100, it may be possible to prevent the formation of cracks in the wirings of the display panel 100 in the third area A3 and improve the reliability of the display device 1.

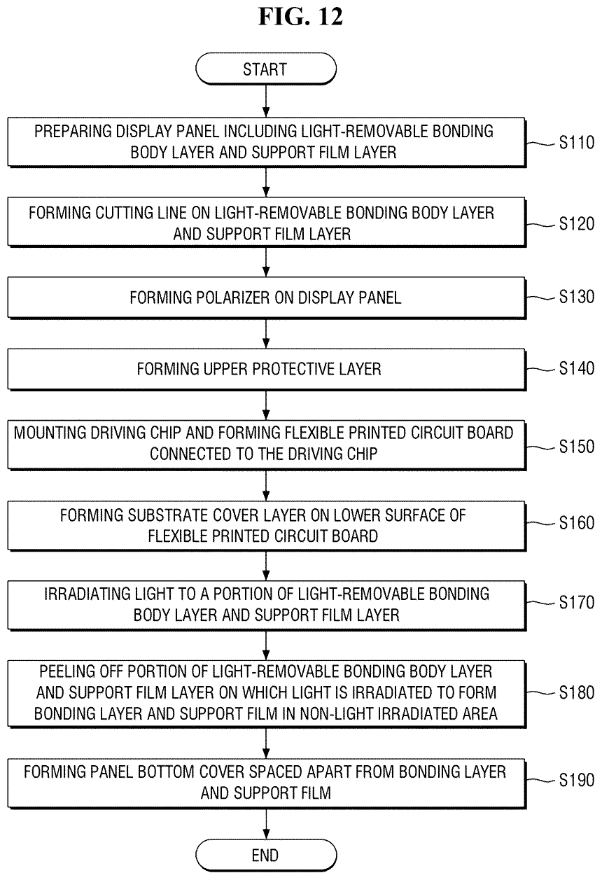

A method of manufacturing the display device 1 according to the disclosure will now be described with reference to FIGS. 12 through 20.

As illustrated in FIG. 12, the manufacturing method of the display device 1 according to the disclosure includes preparing a display panel 100 including a light-peelable bonding body layer 410a and a support film layer 400a (S110), forming a cutting virtual line 650 on the light-peelable bonding body layer 410a and the support film layer 400a (S120), forming a polarizer 310 on the display panel 100 (S130), forming an upper protective layer 600a on the display panel 100 (S140), mounting the driving chip IC and forming a flexible printed circuit board FPCB electrically connected to the driving chip IC (S150), forming a substrate cover layer 500 on the lower surface of the flexible printed circuit board FPCB (S160), irradiating light to a portion of the light-peelable bonding body layer and the support film layer (S170), peeling off the portion of the light-peelable bonding body layer and the support film layer on which light may be irradiated to form a bonding layer 410 and a support film 400 in a non-light irradiated area (S180), and forming an panel bottom cover 300 spaced apart from the bonding layer 410 and the support film 400 (S190).

In the preparing the display panel 100 (S110), the light-peelable bonding body layer 410a including a light-peelable adhesive may be formed on the entire lower surface 101 of the display panel 100, and the display panel in which the support film layer 400a may be attached on the entire lower surface of the light-peelable bonding body layer 410a may be prepared.

Here, the display panel 100 may be a display panel 100 including a first area A1 including the display area DA, a second area A2 spaced apart from the first area A1, and a third area A3 located between the first area A1 and the second area A2.

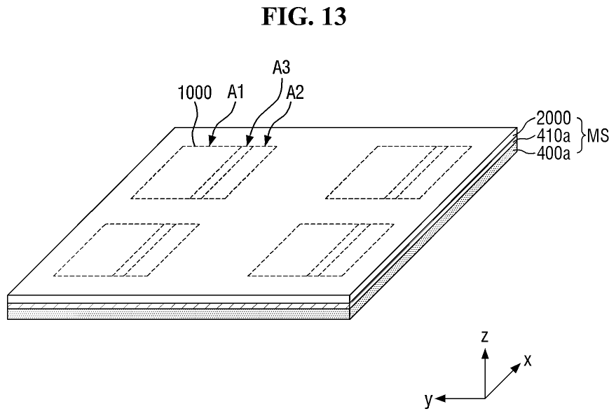

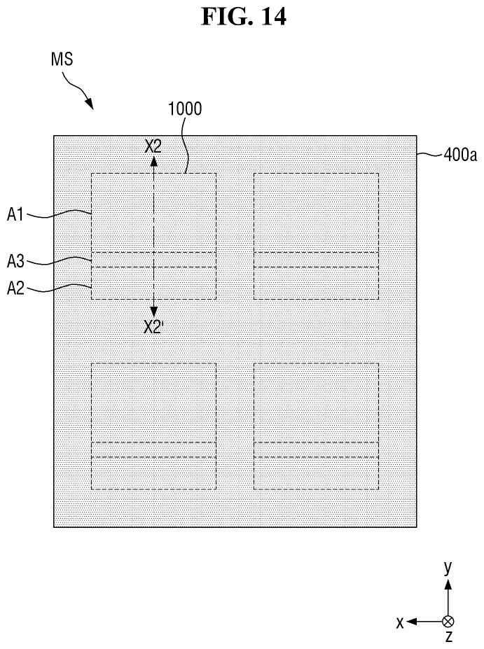

The preparing the display panel 100 (S110) will be described in reference to FIGS. 13 and 14.

A mother substrate 2000 may be formed, the light-peelable bonding body layer 410a may be formed on the lower surface of the mother substrate 2000, and the light-peelable bonding body layer 410a may be combined with the support film layer 400a in a raw state to manufacture a mother substrate structure MS.

The mother substrate 2000 may include multiple display cells 1000 and a dummy area other than the display cells 1000. Each display cell 1000 may share one substrate, and the display cells 1000 may be separated from the mother substrate 2000 to form the display panel 100 later. The cross-sectional stacked structure of each display cell 1000 may be the same as that of the display panel 100 illustrated in FIG. 5 or 6. Each of the display cells 1000 may include the first area A1, the second area A2, and the third area A3.

The dummy area may be disposed between each of the display cells 1000. The dummy area may be disposed around the display cells 1000 and surround each of the display cells 1000. The dummy area may be an area finally removed during the manufacturing process.

The forming of the cutting virtual line 650 (S120) may form the cutting virtual line 650 in the support film layer 400a and the light-peelable bonding body layer 410a. The cutting virtual line 650 may be formed as a boundary virtual line between the second area A2 and the third area A3 in the short side direction of the display panel 100.

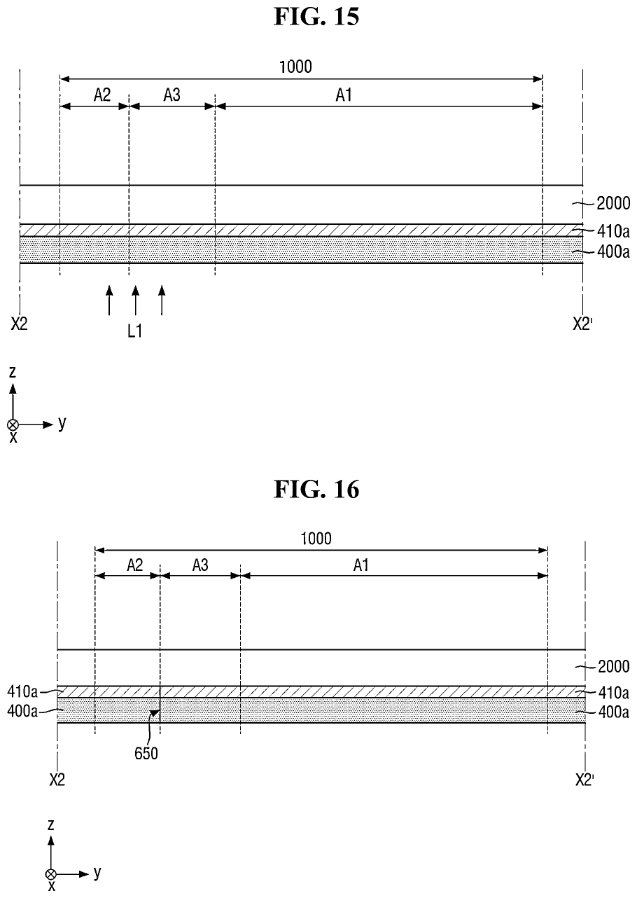

The forming the cutting virtual line 650 (S120) will be described in reference to FIGS. 15 to 17. A laser L1 of FIG. 15 may be irradiated to cut from the lower side of the support film layer 400a in a raw state.

The laser L1 may be irradiated in the first direction x which may be a short side direction of the display panel 100 so that the boundary virtual line between the second area A2 and the third area A3 may be formed as the cutting virtual line 650 of FIG. 16, and the light-peelable bonding body layer 410a and the support film layer 400a may be cut together. Here, the laser light L1 may be, but is not limited to, CO₂ laser light with high energy efficiency.

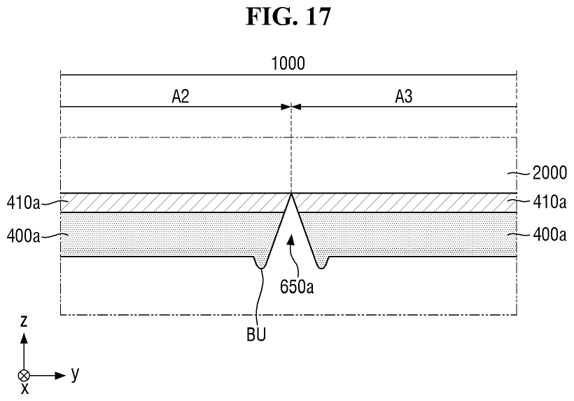

In a cutting virtual line area 650a of the cutting virtual line 650 formed during the process of irradiating the laser L1, a burr pattern BU may be formed on a cut surface of the support film layer 400a in a raw state as illustrated in FIG. 17. The burr pattern BU may be formed in the boundary between the third area A3 and the second area A2. The burr pattern BU may be formed as a portion of the support film layer 400a in a raw state melted by the thermal energy of the laser light L1.

Thereafter, a portion corresponding to the dummy area may be removed from the mother substrate structure MS to separate the display cells 1000 in a shape of FIG. 14. The separated display cells 1000 may include the display panel 100, the light-peelable bonding body layer 410a and the support film layer 400a.

In the forming the polarizer 310 (S130), the polarizer 310 may be formed on the upper surface 102 of the display panel 100 in the first area A1.

In the forming the upper protective layer 600a (S140), the upper protective layer 600a may be formed on the upper surface 102 of the display panel 100 in the third area A3. Although only the upper protective layer 600a may be formed in the drawing, an operation of forming a lower protective layer 600b on the lower surface 101 of the display panel 100 may be further included.

In the forming the driving chip IC and the flexible printed circuit board FPCB (S150), the driving chip IC may be mounted on the upper surface 102 of the display panel 100 in the second area A2 and the flexible printed circuit board FPCB may be bonded to the display panel 100.

In the forming the substrate cover layer 500 (S160), the substrate cover layer 500 may be formed on the lower surface of the flexible printed circuit board FPCB. The substrate cover layer 500 may be adjacently disposed in the distal area of the display panel 100.

The irradiating light (S170) may include placing a mask 700 on the lower side of the support film layer 400a and the light-peelable bonding body layer 410a in which the cutting virtual line 650 may be formed and irradiating light toward the mask 700.

The mask 700 in which a light transmitting portion 701 corresponding to the first and third areas A1 and A3 based on the cutting virtual line 650 and a light blocking portion 702 corresponding to the second area A2 may be disposed.

Light may be irradiated by dividing a partial area of the light-peelable bonding body layer 410a and the support film layer 400a located in the first and third areas A1 and A3 as a light irradiation area through the light transmitting portion 701, and a partial area of the light-peelable bonding body layer 410a and the support film layer 400a located in the second area A2 as a non-irradiated area shielded by the light blocking portion 702.

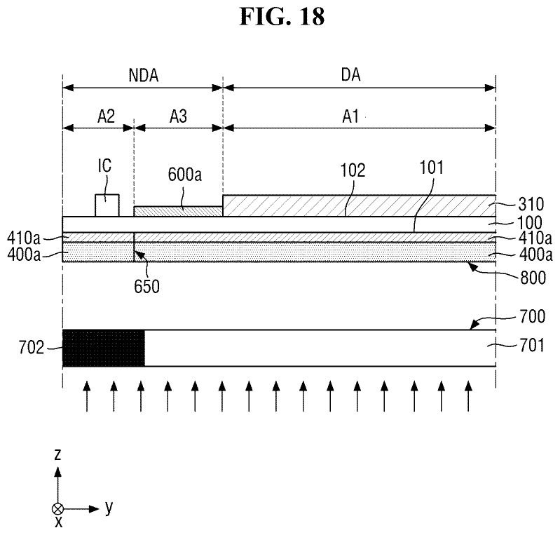

Irradiating light (S170) will be described with reference to FIG. 18.

The mask 700 in which light can pass through selectively may be placed on the lower side of the support film layer 400a on which the cutting virtual line 650 may be formed and light may be irradiated.

A partial area of the light-peelable bonding body layer 410a and the support film layer 400a located in the first and third areas A1 and A3 may be the light irradiation area, and light may be irradiated through the light transmitting portion 701 of the mask 700. The partial area of the light-peelable bonding body layer 410a and the support film layer 400a located in the second area A2 may be the non-irradiated area shielded by the light blocking portion 702, and light may not be irradiated. Here, the light irradiation laser L1 may be irradiation of UV laser light.

In case that UV light is irradiated, the adhesive strength of the light-peelable bonding body layer 410a may be weakened in the first and third areas A1 and A3 irradiated with the light, and the adhesive strength of the light-peelable bonding body layer 410a may be maintained in the second area A2 not irradiated with the light.

For example, the adhesive strength of the light-peelable bonding body layer 410a may be about 250 gf/inch or more before UV irradiation, but as the adhesive strength of the light-peelable bonding body layer 410a decreases to about 100 gf/inch (about 180 degree peeling, speed about 40 mm/sec) or less after irradiation, the support film layer 400a in the light irradiation area can be readily removed. Accordingly, since the light-peelable bonding body layer 410a and the support film layer 400a do not remain in a peeling area which may be a light irradiation area, they do not cause defects or leave damage to a peeled surface, thereby reducing a defect rate. Issues such as tearing during the peeling process can be suppressed. The adhesive strength may also be reduced to about 20 gf/inch or less, but the disclosure may be not limited thereto.

The forming the bonding layer 410 and the support film 400 (S180) includes peeling and removing the partial area of the light-peelable bonding body layer 410a and the partial area of the support film layer 400a of the light irradiation area along the cutting virtual line 650.

As the light irradiation area in the first and third areas A1 and A3 may be formed as a peeling area 800 and the non-irradiated area in the second area A2 may be formed as a bonding area 900, a bonding layer 410 and a support film 400 bonded to the lower surface 101 of the display panel 100 by the bonding layer 410 may be formed on the lower surface 101 of the display panel 100 in the second area A2.

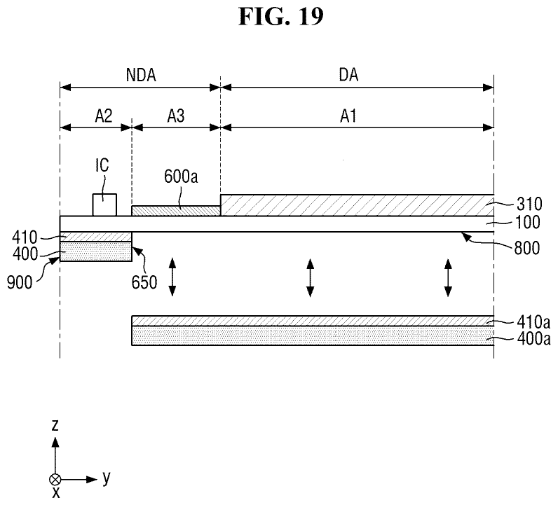

The forming the bonding layer 410 and the support film 400 (S180) will be described in reference to FIG. 19.

A partial area of the light-peelable bonding body layer 410a and a partial area of the support film layer 400a in the light irradiation area may be removed by peeling along the cutting virtual line 650.

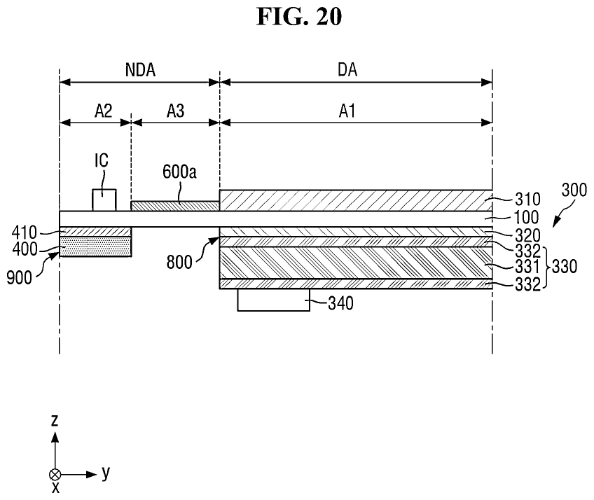

Since the light irradiation area may be formed as the peeling area 800 in the first and third areas A1 and A3 of FIG. 19, and the non-irradiated area may be formed as the bonding area 900 in the second area A2 of FIG. 20, the bonding layer 410 and the support film 400 bonded to the lower surface 101 of the display panel 100 by the bonding layer 410 may be formed on the lower surface 101 of the display panel 100 in the second area A2.

The forming the panel bottom cover 300 (S190) may include forming the panel bottom cover 300 on the lower surface 101 of the display panel 100 at a location corresponding to the first area A1 of the peeling area 800. The panel bottom cover 300 may be formed at a position spaced apart from the bonding layer 410 and the support film 400 of the bonding area 900 by the third area A3 between the panel bottom cover 300 and each of the bonding layer 410 and the support film 400.

The forming the panel bottom cover 300 (S190) will be described in reference to FIG. 20.

The panel bottom cover 300 may be formed on the lower surface 101 of the display panel 100 at a position corresponding to the first area A1 of the peeling area 800. Accordingly, as illustrated in FIG. 20, the panel bottom cover 300 may be formed at a position spaced apart from the bonding layer 410 and the support film 400 of the bonding area 900 with the third area A3 between the panel bottom cover 300 and each of the support film 400 and the bonding layer 410. Through these processes, the display device 1 according to the disclosure can be manufactured.

According to the manufacturing method of the disclosure, a display device capable of reducing thickness and manufacturing costs may be provided.

In concluding the detailed description, those skilled in the art will appreciate that many variations and modifications can be made to the embodiments without substantially departing from the principles of the disclosure. Therefore, the disclosed embodiments of the disclosure may be used in a generic and descriptive sense only and not for purposes of limitation. Each component specifically shown in the embodiments of the disclosure can be implemented by modification, and such modifications and differences related to application should be construed as being included in the scope of the disclosure defined in the appended claims.

What is claimed is:

1. A display device comprising:
a display panel comprising a first area comprising a display area, a second area spaced apart from the first area, and a bendable third area located between the first area and the second area;
a panel bottom cover bonded to a lower surface of the display panel in the first area;
a support film bonded to the lower surface of the display panel in the second area; and
a bonding layer and bonding the support film to the lower surface of the display panel,
wherein a gap is disposed in the third area between the panel bottom cover and the support film.

2. The display device of claim 1, wherein the panel bottom cover comprises:
a heat dissipation member bonded to the lower surface of the display panel in the first area and dissipating heat from the display panel;
an adhesive member bonding the heat dissipation member to the display panel; and
a bending adhesive member located at the lower surface of the heat dissipation member and fixing a bent position of the display panel in case that the display panel is bent.

3. The display device of claim 2, wherein the heat dissipation member comprises:
a metal layer; and
a plating layer disposed on at least one surface among an upper surface and a lower surface of the metal layer.

4. The display device of claim 2, wherein the adhesive member comprises a light absorbing material that bonds the heat dissipation member to the lower surface of the display panel and absorbs light irradiated from outside.

5. The display device of claim 1, wherein the support film further comprises a burr pattern protruding downward from a lower surface of the support film along an inner surface around the gap.

6. The display device of claim 1, wherein an angle formed by a connection surface connecting an inner surface of the bonding layer and an inner surface of the support film and the lower surface of the display panel is about 70 degrees or less.

7. The display device of claim 1, wherein
the bonding layer includes a light-peelable adhesive, and
an adhesive strength after irradiation is about 100 gf/in or less.

8. The display device of claim 1, wherein
the support film comprises at least one of polyethylene terephthalate (PET), polycarbonate (PC), and polymethyl methacrylate (PMMA), and
the bonding layer comprises at least one of polyester acrylate resin, unsaturated polyester resin, polyurethane acrylate resin, epoxy acrylate resin, epoxy resin, polyether acrylate resin, and polythiol acrylate resin.

9. The display device of claim 1, further comprising:
a driving chip disposed in the second area of the display panel and located on an upper surface of the display panel.

10. The display device of claim 9, further comprising:
a flexible printed circuit board electrically connected to the driving chip of the second area; and
a substrate cover layer disposed on a lower surface of the flexible printed circuit board.

11. The display device of claim 10, wherein
the flexible printed circuit board has an end bonded to a distal portion of the display panel in the second area, and
the substrate cover layer is located on the lower surface of the flexible printed circuit board at the distal portion of the display panel and contacts a side surface of the display panel, a side surface of the bonding layer and a side surface of the support film in the second area.

12. The display device of claim 11, wherein the substrate cover layer further comprises:
a cover portion extending from a lower surface of the substrate cover layer toward the side surface of the support film which contacts the substrate cover layer and covering a portion of a lower area of the support film.

13. The display device of claim 1, further comprising:
a protective layer disposed on at least one of an upper surface and the lower surface of the display panel in the third area.

14. A display device comprising:
a display panel comprising a first area comprising a display area, a second area spaced apart from the first area, and a bendable third area located between the first area and the second area;
a support film bonded to a lower surface of the display panel in the second area;
a bonding layer and bonding the support film to the lower surface of the display panel in the second area;
a flexible printed circuit board having an end bonded to a distal portion of the display panel in the second area; and
a substrate cover layer disposed on a lower surface of the flexible printed circuit board.

15. The display device of claim 14, wherein the substrate cover layer further comprises:
a cover portion extending from a lower surface of the substrate cover layer toward a side surface of the support film which contacts the substrate cover layer and covering a portion of a lower area of the support film.

16. The display device of claim 14, further comprising:
a panel bottom cover disposed in the first area of the display panel and bonded to the lower surface of the display panel.

17. The display device of claim 16, wherein
the panel bottom cover comprises a heat dissipation member bonded to the lower surface of the display panel in the first area and dissipating heat from the display panel,
an adhesive member disposed between the heat dissipation member and the lower surface of the display panel and bonding the heat dissipation member to the display panel,
a bending adhesive member located at the lower surface of the heat dissipation member and fixing a bent position of the display panel in case that the display panel is bent,
the third area comprises a gap which is a separation space formed between the support film and the heat dissipation member, and
the support film further comprises a burr pattern protruding downward from the lower surface of the support film along an inner surface around the gap.

18. The display device of claim 17, further comprising:
a driving chip disposed in the second area of the display panel and located on an upper surface of the display panel.

19. The display device of claim 18, further comprising:
a protective layer disposed on at least one of the upper surface and the lower surface of the display panel and in the third area.

20. A method of manufacturing a display device, the method comprising:
providing the display device that includes a display panel which comprises a first area comprising a display area, a second area spaced apart from the first area, and a bendable third area comprising a gap between the first area and the second area, a support film layer disposed on an entire lower surface of the display panel in the first through third areas, and a light-peelable bonding body layer bonding the support film layer to the display panel;
forming a cutting virtual line in the light-peelable bonding body layer and the support film layer at a boundary virtual line between the second area and the third area;
selectively irradiating light to the first and third areas of the light-peelable bonding body layer and the support film layer in which the cutting virtual line is formed;
forming the light-peelable bonding body layer into a bonding layer in the second area and forming the support film layer into a support film in the second area by peeling and removing the light-peelable bonding body layer and the support film layer of the first and third areas irradiated with the light; and
forming a panel bottom cover in the first area at a position spaced apart from the bonding layer and the support film of the second area with the gap disposed between the panel bottom cover and each of the bonding layer and the support film.
